(19) United States
(12) Patent Application Publication
(10) Pub. No.: US 2024/0276843 A1
(43) Pub. Date: Aug. 15, 2024

(54) DISPLAY MODULE AND METHOD OF MANUFACTURING DISPLAY MODULE

(71) Applicant: SAMSUNG DISPLAY CO., LTD., YONGIN-SI (KR)

(72) Inventors: Wonchul LEE, YONGIN-SI (KR); Seunghwan BAEK, YONGIN-SI (KR); Minsuk CHUNG, YONGIN-SI (KR)

(21) Appl. No.: 18/509,087

(22) Filed: Nov. 14, 2023

(30) Foreign Application Priority Data
Feb. 10, 2023 (KR) 10-2023-0017880

(51) Int. Cl. H10K 59/80; H10K 59/12

(52) U.S. Cl. CPC H10K 59/873; H10K 59/1201

(57) ABSTRACT

A display module includes a display panel having an opening area, and a protective film covering the opening area. The protective film includes a first film layer shielding the opening area, the first film layer being transparent, a second film layer disposed between the display panel and the first film layer, the second film layer being opaque, a first adhesive layer disposed between the first film layer and the second film layer, and a second adhesive layer disposed between the second film layer and the display panel.

### CROSS-REFERENCE TO RELATED APPLICATION

This application is based on and claims priority under 35 U.S.C. § 119 to Korean Patent Application No. 10-2023-0017880, filed on Feb. 10, 2023 in the Korean Intellectual Property Office, the disclosure of which is incorporated by reference herein in its entirety.

### TECHNICAL FIELD

Embodiments of the present disclosure relate to a display module and a method of manufacturing the display module, and more particularly, to a display module that may lower the probability of damage occurring during a manufacturing process and a method of manufacturing the same.

### DISCUSSION OF RELATED ART

Electronic devices may provide visual information, such as images or video, to users in order to support various functions. In general, an electronic device may include components such as a display module and a battery electrically connected thereto. A display module typically includes display elements disposed in a display area that are used to display an image. Various additional functions have recently been added to display modules.

### SUMMARY

One or more embodiments include a display module that may lower the probability of damage occurring during a manufacturing process of a display module, and a method of manufacturing the same.

According to one or more embodiments, a display module includes a display panel having an opening area, and a protective film covering the opening area. The protective film includes a first film layer shielding the opening area, the first film layer being transparent, a second film layer disposed between the display panel and the first film layer, the second film layer being opaque, a first adhesive layer disposed between the first film layer and the second film layer, and a second adhesive layer disposed between the second film layer and the display panel.

The display module may further include a component disposed in the opening area.

A circumferential line of the first film layer may coincide with a circumferential line of the second film layer in a plan view.

A circumferential line of the first adhesive layer and a circumferential line of the second adhesive layer may coincide with the circumferential line of the first film layer and the circumferential line of the second film layer in the plan view.

The protective film may further include an alignment pattern formed on at least a portion of a circumference of the protective film.

The alignment pattern may have a first concave portion that is concave at a first corner where a first edge of the protective film meets a second edge of the protective film.

The alignment pattern may have a second concave portion that is concave at a second corner where the second edge of the protective film meets a third edge of the protective film, and the first concave portion and the second concave portion may have shapes concavely recessed at a same angle.

The alignment pattern may include a first pattern formed on at least a portion of a circumference of the first film layer, and a second pattern overlapping the first pattern on a circumference of the second film layer.

The alignment pattern may further include a third pattern overlapping the second pattern on the circumference of the first adhesive layer, and a fourth pattern overlapping the second pattern on a circumference of the second adhesive layer.

The second film layer may have a first opening corresponding to the opening area.

The second film layer may form a closed loop along the circumference of the first film layer.

The first adhesive layer and the second adhesive layer may respectively have a second opening and a third opening, which overlap the first opening in a plan view.

The protective film may further include a concave portion disposed on one side of a circumference of the protective film.

The display module may further include a gripping portion disposed on one side of the first film layer and including a transparent material.

According to one or more embodiments, a display module includes a display panel having an opening area, and a protective film covering the opening area. The protective film includes a first film layer shielding the opening area, the first film layer being transparent, a second film layer disposed on a side of the first film layer opposite to the display panel, the second film layer being opaque, a first adhesive layer disposed between the first film layer and the second film layer, and a second adhesive layer disposed between the first film layer and the display panel.

A circumferential line of the first film layer may coincide with a circumferential line of the second film layer in a plan view.

The protective film may further include an alignment pattern formed on at least a portion of a circumference of the protective film.

According to one or more embodiments, a method of manufacturing a display module includes forming a film assembly layer by sequentially stacking a transparent first film layer, a first adhesive layer, an opaque second film layer, and a second adhesive layer in a thickness direction, forming a protective film by cutting the film assembly layer in the thickness direction to form a pattern on a circumference of the film assembly layer in a plan view, aligning the protective film with a display panel by recognizing the pattern of the protective film, and attaching the protective film to cover an opening area of the display panel.

The second film layer may have a first opening exposing the opening area of the display panel inside a circumference of the second film layer.

The method may further include inspecting a component inside the opening area through the first opening from outside of the protective film.

### BRIEF DESCRIPTION OF THE DRAWINGS

The above and other features of the present disclosure will become more apparent by describing in detail embodiments thereof with reference to the accompanying drawings, in which:

FIG. 1 is a perspective view schematically illustrating a display module according to an embodiment;

FIG. 2 is a perspective view schematically illustrating a display module according to an embodiment;

FIG. 3 is a cross-sectional view schematically illustrating an example of a cross-section I-I′ in FIG. 1;

FIG. 4 is a cross-sectional view schematically illustrating a display panel according to an embodiment;

FIG. 5 is an exploded perspective view schematically illustrating a protective film according to an embodiment;

FIG. 6 is a plan view schematically illustrating a protective film according to an embodiment;

FIG. 7 is an exploded perspective view schematically illustrating a protective film according to an embodiment; and

FIGS. 8 and 9 are views schematically illustrating a method of manufacturing a display module according to an embodiment.

### DETAILED DESCRIPTION

Embodiments of the present disclosure will be described more fully hereinafter with reference to the accompanying drawings. Like reference numerals may refer to like elements throughout the accompanying drawings.

As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

It will be understood that the terms “first,” “second,” “third,” etc. are used herein to distinguish one element from another, and the elements are not limited by these terms. Thus, a “first” element in an embodiment may be described as a “second” element in another embodiment.

As used herein, the singular forms “a”, “an” and “the” are intended to include the plural forms as well, unless the context clearly indicates otherwise.

It will be understood that the terms “include”, “comprise”, and/or “have” used herein specify the presence of stated features or components, but do not preclude the presence or addition of one or more other features or components.

It will be understood that when a component such as a film, a region, a layer, etc., is referred to as being “on”, “connected to”, “coupled to”, or “adjacent to” another component, it can be directly on, connected, coupled, or adjacent to the other component, or intervening components may be present. It will also be understood that when a component is referred to as being “between” two components, it can be the only component between the two components, or one or more intervening components may also be present. It will also be understood that when a component is referred to as “covering” another component, it can be the only component covering the other component, or one or more intervening components may also be covering the other component. Other words used to describe the relationships between components should be interpreted in a like fashion.

The x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

When a certain embodiment may be implemented differently, a specific process order may be performed differently from the described order. For example, two consecutively described processes may be performed substantially at the same time or performed in an order opposite to the described order.

Spatially relative terms, such as “beneath,” “below,” “lower,” “above,” “upper,” etc. may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

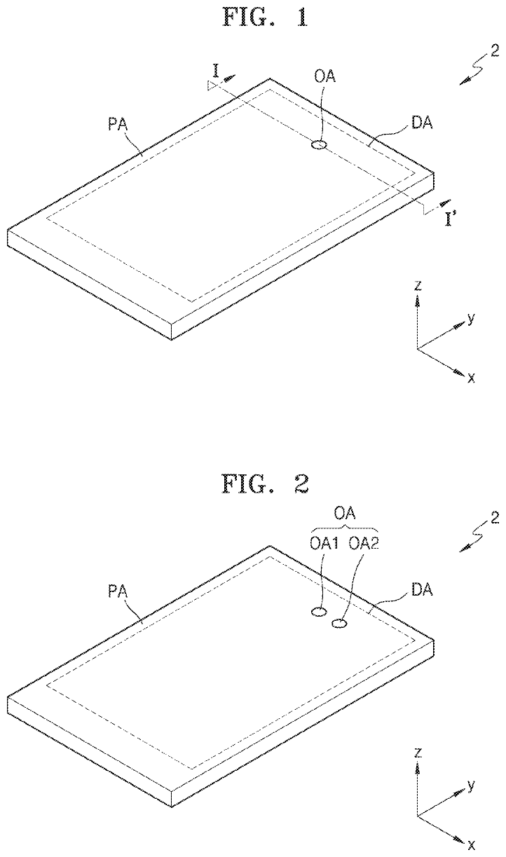

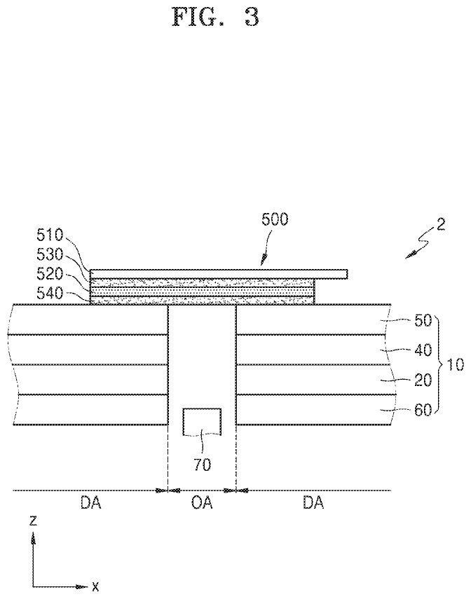

FIG. 1 is a perspective view schematically illustrating a display module 2 according to an embodiment. FIG. 2 is a perspective view schematically illustrating a display module 2 according to an embodiment.

Referring to FIG. 1, the display module 2 according to an embodiment may be a portion of a display device. Thus, the display module 2 may also be referred to herein as a display device. The display device may display a moving image or a still image, and may be used as a display screen in various products including, for example, televisions, notebook computers, monitors, advertisement boards, Internet of Things (IoT) apparatuses, as well as portable electronic apparatuses including, for example, mobile phones, smartphones, tablet personal computers (PC), mobile communication terminals, electronic organizers, electronic books, portable multimedia players (PMP), navigation devices, and ultra mobile personal computers (UMPC). Also, the display device according to an embodiment may be a wearable device such as, for example, a smartwatch, a watch phone, a glasses-type display, and a head mounted display (HMD). In addition, the display device according to an embodiment may be used as, for example, a dashboard of a vehicle, a center information display (CID) disposed on a center fascia or dashboard of a vehicle, a room mirror display that replaces a side mirror of a vehicle, an entertainment unit for a back seat of a vehicle, and a display disposed on the back of a front seat of a vehicle. FIG. 1 illustrates an example in which the display device according to an embodiment is used as a smartphone for convenience of description.

In an embodiment, the display module 2 may have a rectangular shape in a plan view. For example, the display module 2 may have a rectangular plane shape having short sides extending in the x direction and long sides extending in the y direction, as shown in FIG. 1. Corners where the short sides extending in the x direction meet the long sides extending in the y direction may be round to have a certain curvature, or may be formed at a right angle. The planar shape of the display module 2 is not limited to a rectangle and may be another polygonal, elliptical, or atypical shape.

The display module 2 may include an opening area OA and a display area DA at least partially surrounding the opening area OA. The display module 2 may include a peripheral area PA surrounding the display area DA, for example, outside the display area DA.

The opening area OA may be positioned inside the display area DA. As an example, the opening area OA may be disposed in the upper center of the display area DA, as shown in FIG. 1. Alternatively, the opening area OA may be disposed in various ways, such as being disposed on the upper left side of the display area DA or disposed on the upper right side of the display area DA. Also, the opening area OA may be disposed in the middle of the display area DA or on a lower side of the display area DA. Although FIG. 1 shows that one opening area OA is disposed in the display module 2, the disclosure is not limited thereto. For example, in an embodiment, a plurality of opening areas OA, for example, two opening areas OA, may be provided as shown in FIG. 2.

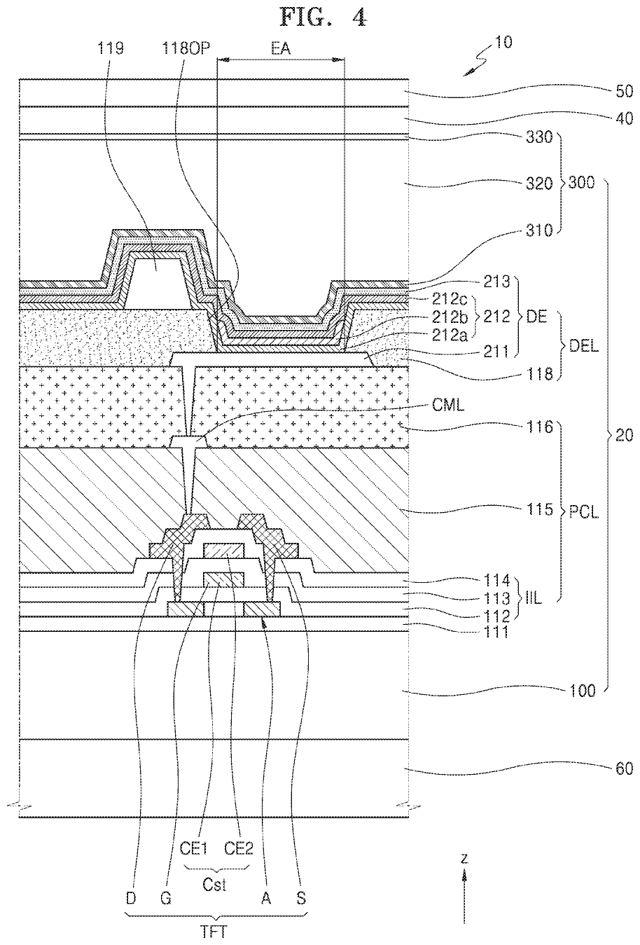

The opening area OA may be an area where a component capable of imparting various functions to the display device is disposed. For example, when the component includes a sensor or a camera that uses light, the opening area OA corresponds to a transmissive area through which light from the sensor or light traveling to the camera may pass. Also, when a plurality of opening areas OA are provided as shown in FIG. 2, components having different functions may be respectively disposed in the different opening areas OA. For example, a camera may be disposed under a display panel 10 (see FIG. 3) to correspond to a first opening area OA1, and an illuminance sensor and/or a proximity sensor may be disposed under the display panel 10 to correspond to a second opening area OA2 in an embodiment.

A plurality of pixels, for example, an array of pixels, may be arranged in the display area DA, and an image may be displayed through the array of pixels. The opening area OA may be entirely surrounded by the display area DA. Each pixel provided in the display module 2 may include a light-emitting diode as a display element capable of emitting light of a certain color. The light-emitting diode may include an organic light-emitting diode including an organic emission layer.

Alternatively, the light-emitting diode may include an inorganic light-emitting diode including an inorganic material. The inorganic light-emitting diode may include a PN junction diode including inorganic semiconductor-based materials. When a forward voltage is applied to the PN junction diode, holes and electrons may be injected, and energy generated by recombination of the holes and electrons may be converted into light energy to emit light of a certain color. The aforementioned inorganic light-emitting diode may have a width of several micrometers to several hundred micrometers or several nanometers to several hundred nanometers.

Alternatively, the light-emitting diode may include a quantum dot light-emitting diode.

That is, the emission layer of the light-emitting diode may include an organic material, may include an inorganic material, may include quantum dots, may include an organic material and quantum dots, or may include an inorganic material and quantum dots according to embodiments. Hereinafter, for convenience of description, a case in which the light-emitting diode includes an organic light-emitting diode will be mainly described.

The peripheral area PA surrounding the display area DA may be a non-display area in which pixels are not arranged, and various types of wires and embedded circuits may be arranged in the peripheral area PA.

FIG. 3 is a cross-sectional view schematically illustrating an example of a cross-section I-I′ in FIG. 1.

Referring to FIG. 3, the display module 2 may include the display panel 10 and a component 70 overlapping the display panel 10. In addition, the display module 2 may include a protective film 500 attached to the display panel 10.

The display panel 10 may include an image generating layer 20, an input sensing layer 40, an optical function layer 50, and a panel protecting member 60.

The image generating layer 20 may include display elements that emit light to display an image. Each of the display elements may include a light-emitting diode, for example, an organic light-emitting diode including an organic emission layer. In an embodiment, the light-emitting diode may be an inorganic light-emitting diode including an inorganic material. The inorganic light-emitting diode may include a PN junction diode including inorganic semiconductor-based materials. When a forward voltage is applied to the PN junction diode, holes and electrons may be injected, and energy generated by recombination of the holes and electrons may be converted into light energy to emit light of a certain color. The aforementioned inorganic light-emitting diode may have a width of several micrometers to several hundred micrometers or several nanometers to several hundred nanometers. In some embodiments, the image generating layer 20 may include a quantum dot light-emitting diode. For example, the emission layer of the image generating layer 20 may include an organic material, may include an inorganic material, may include quantum dots, may include an organic material and quantum dots, or may include an inorganic material and quantum dots.

The input sensing layer 40 may obtain coordinate information according to an external input, for example, a touch event. The input sensing layer 40 may include a sensing electrode (or touch electrode) and signal lines (e.g., trace lines) connected to the sensing electrode. The input sensing layer 40 may be disposed on the image generating layer 20. The input sensing layer 40 may sense an external input by using a mutual capacitance method and/or a self-capacitance method.

The input sensing layer 40 may be formed directly on the image generating layer 20, or may be formed separately from the image generating layer 20 and then bonded to the image generating layer 20 through an adhesive layer, such as an optically transparent adhesive. In an embodiment, the input sensing layer 40 may be continuously formed after the process of forming the image generating layer 20, and in this case, the adhesive layer is not disposed between the input sensing layer 40 and the image generating layer 20. FIG. 3 shows that the input sensing layer 40 is disposed between the image generating layer 20 and the optical function layer 50, however, the present disclosure is not limited thereto. For example, in an embodiment, the input sensing layer 40 may be disposed on the optical function layer 50.

The optical function layer 50 may include an antireflection layer. The antireflection layer may reduce reflectance of light (external light) incident toward the display panel 10 from outside of the display panel 10. The antireflection layer may include a retarder and a polarizer. In an embodiment, the antireflection layer may include a black matrix and color filters. The color filters may be arranged by considering the color of light emitted from each of the light-emitting diodes of the image generating layer 20.

The panel protecting member 60 may be attached to a lower portion of the image generating layer 20, and may support and protect the image generating layer 20. In an embodiment, the panel protecting member 60 may include a cushion layer.

To increase the transmittance of the opening area OA, the display panel 10 may include a through hole passing through some or all of the layers constituting the display panel 10. The through hole may include first to fourth through holes passing through the image generating layer 20, the input sensing layer 40, the optical function layer 50, and the panel protecting member 60, respectively. The first through hole of the image generating layer 20, the second through hole of the input sensing layer 40, the third through hole of the optical function layer 50, and the fourth through hole of the panel protecting member 60 may overlap one another to form the through hole of the display panel 10.

The opening area OA may be a type of component area (e.g., a sensor area, a camera area, or a speaker area) in which the component 70 for adding various functions to the display device is located.

The component 70 may include an electronic element. For example, the component 70 may be an electronic element that uses light or sound. For example, the electronic element may include a sensor that uses light, such as an infrared sensor, a camera that receives light and captures an image, a sensor that outputs and detects light or sound to measure distance or recognize a fingerprint, a small lamp that outputs light, or a speaker that outputs sound. An electronic element that uses light may use light of various wavelength bands, such as, for example, visible light, infrared light, and ultraviolet light. The opening area OA corresponds to an area through which light and/or sound output from the component 70 to the outside of the display module 2 or traveling from the outside of the display module 2 toward the electronic element may pass.

The protective film 500 may be disposed on the display panel 10. In an embodiment, the protective film 500 may overlap the opening area OA in a plan view. In addition, the protective film 500 may overlap the component 70 in a plan view. The protective film 500 may include a first film layer 510, a second film layer 520, a first adhesive layer 530 and a second adhesive layer 540, which are described in further detail below.

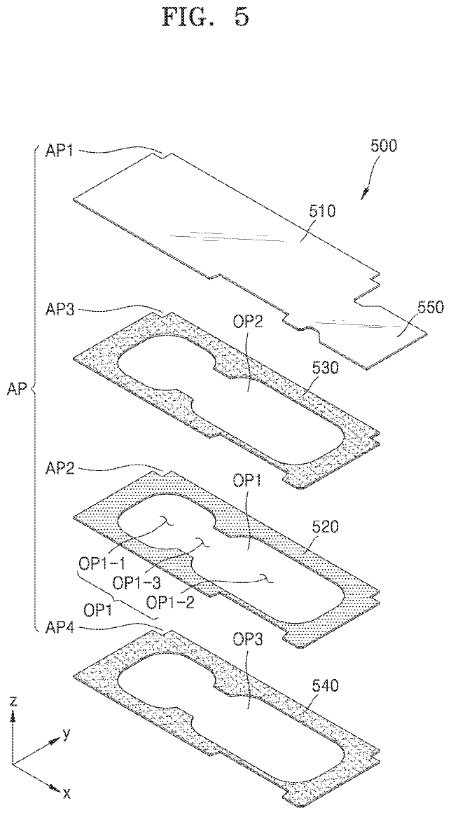

FIG. 4 is a cross-sectional view schematically illustrating a display panel 10 according to an embodiment.

Referring to FIG. 4, the display panel 10 may include an image generating layer 20, an input sensing layer 40, an optical function layer 50 and a panel protecting member 60. Hereinafter, the image generating layer 20 will be described in detail.

The image generating layer 20 may include a substrate 100, a buffer layer 111, a pixel circuit layer PCL, a display element layer DEL, and an encapsulation layer 300.

The substrate 100 may be glass or may include polymer resin, such as, for example, polyethersulfone, polyarylate, polyetherimide, polyethylene naphthalate, polyethylene terephthalate, polyphenylene sulfide, polyimide, polycarbonate, cellulose triacetate, or cellulose acetate propionate. In an embodiment, the substrate 100 may have a multilayer structure including a base layer and a barrier layer, which include the polymer resin described above. The substrate 100 including polymer resin may be flexible, rollable, and bendable.

The buffer layer 111 may be disposed on the substrate 100. The buffer layer 111 may include an inorganic insulating material, such as, for example, silicon nitride, silicon oxynitride, and silicon oxide, and may include a single layer or multiple layers including the aforementioned inorganic insulating material.

The pixel circuit layer PCL may be disposed on the buffer layer 111. The pixel circuit layer PCL may include a transistor TFT included in a pixel circuit, an inorganic insulating layer IIL, a first planarization layer 115, and a second planarization layer 116 disposed below and/or above components of the transistor TFT. The inorganic insulating layer IIL may include a first gate insulating layer 112, a second gate insulating layer 113, and an interlayer insulating layer 114.

The transistor TFT may include a semiconductor layer A. In an embodiment, the semiconductor layer A may include polysilicon. Alternatively, in an embodiment, the semiconductor layer A may include amorphous silicon, an oxide semiconductor, or an organic semiconductor. The semiconductor layer A may include a channel region, a drain region and a source region. The drain region and the source region may be respectively disposed on both sides of the channel region. A gate electrode G may overlap the channel region.

The gate electrode G may include a low-resistance metal material. The gate electrode G may include a conductive material including, for example, molybdenum (Mo), aluminum (Al), copper (Cu), titanium (Ti), or the like, and may include multiple layers or a single layer including the aforementioned material.

The first gate insulating layer 112 disposed between the semiconductor layer A and the gate electrode G may include an inorganic insulating material, such as, for example, silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO_{X}). Zinc oxide (ZnO_{X}) may be zinc oxide (ZnO) and/or zinc peroxide (ZnO₂).

The second gate insulating layer 113 may cover the gate electrode G. Similar to the first gate insulating layer 112, the second gate insulating layer 113 may include an inorganic insulating material, such as, for example, SiO₂, SiNₓ, SiON, Al₂O₃, TiO₂, Ta₂O₅, HfO₂, or ZnO_{X}. ZnO_{X} may be ZnO and/or ZnO₂.

An upper electrode CE2 of a storage capacitor Cst may be disposed on the second gate insulating layer 113. The upper electrode CE2 may overlap the gate electrode G below the upper electrode CE2. In this case, the gate electrode G and the upper electrode CE2 overlapping each other with the second gate insulating layer 113 disposed therebetween may form the storage capacitor Cst of the pixel circuit. That is, the gate electrode G may function as a lower electrode CE1 of the storage capacitor Cst. As such, in some embodiments, the storage capacitor Cst and the transistor TFT may be formed to overlap each other. In some embodiments, the storage capacitor Cst may be formed not to overlap the transistor TFT.

The upper electrode CE2 may include, for example, aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and may include a single layer or multiple layers including the aforementioned material.

The interlayer insulating layer 114 may cover the upper electrode CE2. The interlayer insulating layer 114 may include, for example, SiO₂, SiNₓ, SiON, Al₂O₃, TiO₂, Ta₂O₅, HfO₂, ZnO_{X}, or the like. ZnO_{X} may be ZnO and/or ZnO₂. The interlayer insulating layer 114 may include a single layer or multiple layers including the aforementioned inorganic insulating material.

A drain electrode D and a source electrode S may each be positioned on the interlayer insulating layer 114. The drain electrode D and the source electrode S may include a material having good conductivity. The drain electrode D and the source electrode S may each include a conductive material including, for example, Mo, Al, Cu, Ti, or the like, and may include multiple layers or a single layer including the aforementioned material. In an embodiment, the drain electrode D and the source electrode S may each have a multi-layered structure including Ti/Al/Ti layers.

The first planarization layer 115 may cover the drain electrode D and the source electrode S. The first planarization layer 115 may include an organic insulating layer. The first planarization layer 115 may include, for example, an organic insulating material, such as a general-purpose polymer, such as polymethylmethacrylate (PMMA) or polystyrene (PS), a polymer derivative having a phenolic group, an acryl-based polymer, an imide-based polymer, an aryl ether-based polymer, an amide-based polymer, a fluorine-based polymer, a p-xylene-based polymer, a vinyl alcohol-based polymer, or a blend thereof.

A connection electrode CML may be disposed on the first planarization layer 115. In this case, the connection electrode CML may be connected to the drain electrode D or the source electrode S through a contact hole of the first planarization layer 115. The connection electrode CML may include a material having good conductivity. The connection electrode CML may include a conductive material including, for example, Mo, Al, Cu, Ti, or the like, and may include multiple layers or a single layer including the aforementioned material. In an embodiment, the connection electrode CML may have a multi-layered structure including Ti/Al/Ti layers.

The second planarization layer 116 may cover the connection electrode CML. The second planarization layer 116 may include an organic insulating layer. The second planarization layer 116 may include, for example, an organic insulating material, such as a general-purpose polymer, such as PMMA or PS, a polymer derivative having a phenolic group, an acryl-based polymer, an imide-based polymer, an aryl ether-based polymer, an amide-based polymer, a fluorine-based polymer, a p-xylene-based polymer, a vinyl alcohol-based polymer, or a blend thereof.

The display element layer DEL may be disposed on the pixel circuit layer PCL. The display element layer DEL may include a display element DE. The display element DE may be an organic light-emitting diode (OLED). A pixel electrode 211 of the display element DE may be electrically connected to the connection electrode CML through a contact hole of the second planarization layer 116.

The pixel electrode 211 may include, for example, a conductive oxide, such as indium tin oxide (ITO), indium zinc oxide (IZO), zinc oxide (ZnO), indium oxide (In₂O₃), indium gallium oxide (IGO), or aluminum zinc oxide (AZO). In an embodiment, the pixel electrode 211 may include a reflective film including, for example, Ag, Mg, Al, Pt, Pd, Au, Ni, Nd, Ir, Cr, or a compound thereof. In an embodiment, the pixel electrode 211 may further include a film including, for example, ITO, IZO, ZnO, or In₂O₃ above or below the reflective film.

A pixel-defining layer 118 having an opening 118OP exposing a central portion of the pixel electrode 211 may be disposed on the pixel electrode 211. The pixel-defining layer 118 may include an organic insulating material and/or an inorganic insulating material. The opening 118OP may define an emission area EA of light emitted from the display element DE. For example, the width of the opening 118OP may correspond to the width of the emission area EA of the display element DE.

In an embodiment, the pixel-defining layer 118 may include a light blocking material and may be black. The light blocking material may include, for example, carbon black, carbon nanotube, resin or paste containing black dye, metal particles (e.g., nickel, aluminum, molybdenum, and an alloy thereof), metal oxide particles (e.g., chromium oxide), metal nitride particles (e.g., chromium nitride), or the like. When the pixel-defining layer 118 includes a light blocking material, reflection of external light by metal structures disposed below the pixel-defining layer 118 may be reduced.

A spacer 119 may be disposed on the pixel-defining layer 118. The spacer 119 may prevent damage to the substrate 100 in a manufacturing method of manufacturing a display device. A mask sheet may be used when manufacturing a display panel. In this case, when the mask sheet enters the opening 118OP of the pixel-defining layer 118 or adheres to the pixel-defining layer 118 to deposit a deposition material on the substrate 100, a defect in which a portion of the substrate 100 is damaged or broken by the mask sheet may be prevented.

The spacer 119 may include an organic insulating material, such as, for example, polyimide. Alternatively, the spacer 119 may include an inorganic insulating material, such as, for example, silicon nitride or silicon oxide, or may include an organic insulating material and an inorganic insulating material.

In an embodiment, the spacer 119 may include a material different from that of the pixel-defining layer 118. Alternatively, in an embodiment, the spacer 119 may include the same material as the pixel-defining layer 118. In this case, the pixel-defining layer 118 and the spacer 119 may be formed together in a mask process using a halftone mask or the like.

An intermediate layer 212 may be disposed on the pixel-defining layer 118. The intermediate layer 212 may include an emission layer 212b disposed in the opening 118OP of the pixel-defining layer 118. The emission layer 212b may include a high molecular weight or low molecular weight organic material that emits light of a certain color.

A first functional layer 212a and a second functional layer 212c may be disposed below and above the emission layer 212b, respectively. For example, the first functional layer 212a may include a hole transport layer (HTL) or may include an HTL and a hole injection layer (HIL). The second functional layer 212c may be disposed on the emission layer 212b. In embodiments, the second functional layer 212c may be omitted. The second functional layer 212c may include an electron transport layer (ETL) and/or an electron injection layer (EIL). Similar to an opposite electrode 213 to be described below, the first functional layer 212a and/or the second functional layer 212c may be a common layer formed to entirely cover the substrate 100.

The opposite electrode 213 may include a conductive material having a low work function. For example, the opposite electrode 213 may include a semitransparent layer including, for example, Ag, Mg, Al, Pt, Pd, Au, Ni, Nd, Ir, Cr, lithium (Li), Ca, or an alloy thereof. Alternatively, the opposite electrode 213 may further include a layer including ITO, IZO, ZnO, or In₂O₃ on the semitransparent layer including the material described above.

In some embodiments, a capping layer may be further disposed on the opposite electrode 213. The capping layer may include, for example, LiF, an inorganic material, and/or an organic material.

The encapsulation layer 300 may be disposed on the opposite electrode 213. In an embodiment, the encapsulation layer 300 may include at least one inorganic encapsulation layer and at least one organic encapsulation layer. FIG. 4 shows that the encapsulation layer 300 includes a first inorganic encapsulation layer 310, an organic encapsulation layer 320, and a second inorganic encapsulation layer 330, which are sequentially stacked.

The first inorganic encapsulation layer 310 and the second inorganic encapsulation layer 330 may each include one or more inorganic materials selected from among, for example, aluminum oxide, titanium oxide, tantalum oxide, hafnium oxide, zinc oxide, silicon oxide, silicon nitride, and silicon oxynitride. The organic encapsulation layer 320 may include a polymer-based material. Examples of the polymer-based material may include acryl-based resin, epoxy-based resin, polyimide, and polyethylene. In an embodiment, the organic encapsulation layer 320 may include acrylate.

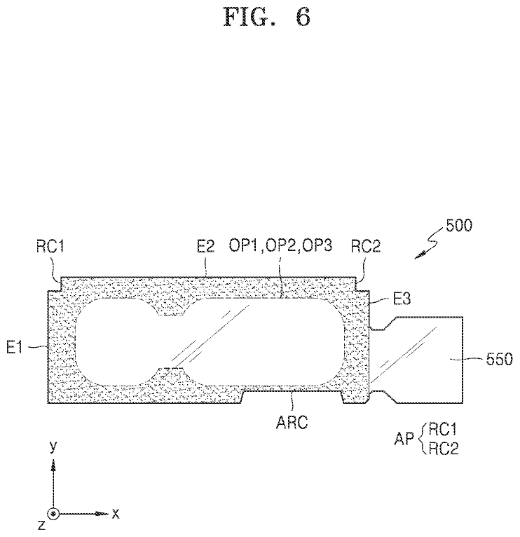

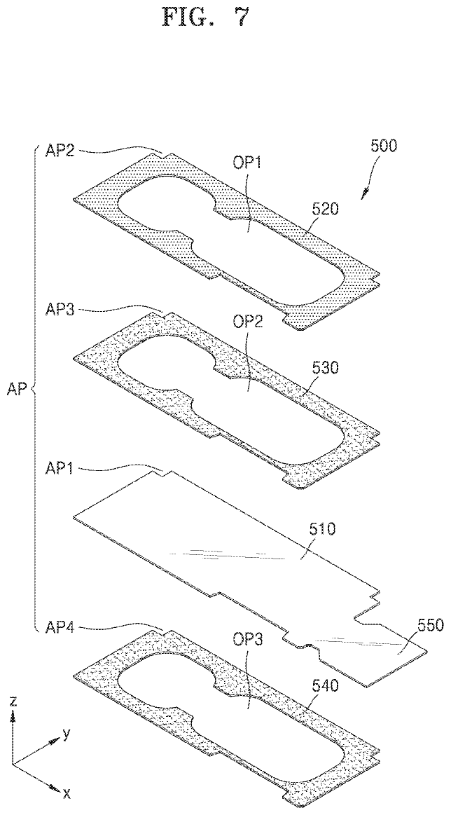

FIG. 5 is an exploded perspective view schematically illustrating a protective film 500 according to an embodiment, and FIG. 6 is a plan view schematically illustrating a protective film 500 according to an embodiment.

Referring to FIGS. 5 and 6, the protective film 500 may include a first film layer 510, a second film layer 520, a first adhesive layer 530 and a second adhesive layer 540.

As described above, the display panel 10 of the display module 2 may have a through hole corresponding to the opening area OA that allows light and/or sound output from the component 70 to the outside of the display module 2 or travelling from the outside of the display module 2 toward the component 70 to pass through. To prevent impurities, such as dust, from penetrating into the through hole of the display module 2 during a manufacturing process, the protective film 500 may be attached to the display panel 10 to shield the through hole of the display panel 10.

The first film layer 510 may shield a portion of the display panel 10 (see FIG. 3), for example, the opening area OA (see FIG. 3). The first film layer 510 may have a larger area than the opening area OA to shield the opening area OA. As the first film layer 510 shields the opening area OA, impurities, such as dust, may be prevented from penetrating into the through hole.

In an embodiment, the first film layer 510 may include a transparent material. The first film layer 510 may include, for example, polyethylene terephthalate (PET) or polyimide. Because the first film layer 510 is transparent, the inspection of the inside of the opening area OA and the component 70 may be performed through the first film layer 510. For example, after the protective film 500 is attached, the presence or absence of foreign materials or stains inside the opening area OA may be inspected.

A gripping portion 550 may be positioned on one side of the first film layer 510. When the display module 2 is combined with other devices to manufacture a display device, the gripping portion 550 may be a portion to be gripped allowing the protective film 500 to be removed. In an embodiment, the gripping portion 550 may be formed integrally with the first film layer 510. The gripping portion 550 may include the same material as the first film layer 510 and may be formed through the same process as the first film layer 510. Accordingly, the gripping portion 550 may include a transparent material.

The second film layer 520 may be disposed between the first film layer 510 and the display panel 10. In an embodiment, the second film layer 520 may include an opaque material. The second film layer 520 may include, for example, polyethyleneterephthalate (PET) or polyimide, but is not limited thereto. The second film layer 520 may include a colored material or a colorless but opaque material. For this reason, the light transmittance of the second film layer 520 may be less than the light transmittance of the first film layer 510.

When attaching the protective film 500 to the display panel 10, the relative positions of the protective film 500 and the display panel 10 may be aligned with each other by using an optical camera while the protective film 500 is held by a vacuum adsorption method or the like, and then the protective film 500 may be attached to the display panel 10. In this case, when the relative positions of the protective film 500 and the display panel 10 are not properly aligned with each other, the protective film 500 may not accurately shield the through hole of the display panel 10.

To align the protective film 500 with the display panel 10 by using an optical camera, the protective film 500 is recognized. Because it may be difficult for the optical camera to recognize a transparent material, the optical camera may recognize the protective film 500 through the second film layer 520 including an opaque material. Because the first film layer 510 and the gripping portion 550 include a transparent material, the first film layer 510 and the gripping portion 550 are not recognized by an optical camera.

Accordingly, in embodiments of the present disclosure, inaccurate alignment between the display panel 10 and the protective film 500 that may be caused by recognizing the end of the gripping portion 550, which is not directly attached to the display panel 10, may be prevented. In addition, according to embodiments of the present disclosure, the position of the protective film 500 is recognized through the second film layer 520 including an opaque material, resulting in a more precise alignment process, while the first film layer 510 including a transparent material allows for inspection of the inside of the through-hole passing through some or all of the layers constituting the display panel 10.

In an embodiment, the second film layer 520 may be formed to have the same size and shape as the first film layer 510. That is, in a plan view, the circumferential line of the second film layer 520 may coincide with the circumferential line of the first film layer 510. As described below, this may be implemented by forming the first film layer 510 and the second film layer 520 in the same cutting process while being attached to each other.

In addition, the second film layer 520 may have a first opening OP1. The first opening OP1 may be an opening formed in the second film layer 520. The first opening OP1 may correspond to the opening area OA. That the first opening OP1 corresponds to the opening area OA may mean that the first opening OP1 overlaps the opening area OA and/or the through hole passing through some or all of the layers constituting the display panel 10 in a plan view. Also, that the first opening OP1 corresponds to the opening area OA may mean that the first opening OP1 has the same size as the opening area OA and/or the through hole passing through some or all of the layers constituting the display panel 10, or has a larger size to cover the opening area OA and/or the through hole passing through some or all of the layers constituting the display panel 10.

FIG. 5 illustrates an embodiment in which a protective film 500 is attached to cover the opening area OA shown in FIG. 2. When a plurality of opening areas OA is provided, as shown in FIG. 2, the first opening OP1 may be an opening corresponding to both the first opening area OA1 and the second opening area OA2.

In an embodiment, the first opening OP1 may be one opening corresponding to the first opening area OA1 and the second opening area OA2, as shown in FIG. 5. In this case, the first opening OP1 may include a first part OP1-1 corresponding to the first opening area OA1, a second part OP1-2 corresponding to the second opening area OA2, and a third part OP1-3 disposed between and connecting the first part OP1-1 and the second part OP1-2. The third part OP1-3 may be positioned on a portion of the display panel 10 positioned between the first opening area OA1 and the second opening area OA2. In an embodiment, the width of the third part OP1-3 may be less than that of the first part OP1-1 and/or that of the second part OP1-2. Accordingly, the first opening OP1 may have a dumbbell shape.

In an embodiment, the first opening OP1 may include a plurality of openings respectively corresponding to the first opening area OA1 and the second opening area OA2. That is, the first opening OP1 may include a first part corresponding to the first opening area OA1 and a second part corresponding to the second opening area OA2, and the first part and the second part may be spaced apart from each other. Hereinafter, for convenience of description, a case in which the first opening OP1 is the same as that of FIG. 5 will be mainly described.

Accordingly, the second film layer 520 may form a closed loop along the circumference of the first film layer 510. In an embodiment, the second film layer 520 may overlap the first film layer 510 at its periphery and does not overlap the first film layer 510 at its center.

The first adhesive layer 530 may be disposed between the first film layer 510 and the second film layer 520. The second adhesive layer 540 may be disposed between the second film layer 520 and the display panel 10. The first adhesive layer 530 may attach the first film layer 510 and the second film layer 520 to each other. The second adhesive layer 540 may attach the second film layer 520 and the first film layer 510 attached thereto to the display panel 10. The first adhesive layer 530 and the second adhesive layer 540 may each include, for example, pressure sensitive adhesive (PSA).

In an embodiment, the first adhesive layer 530 and the second adhesive layer 540 may be the same member, and may differ only in their positions. Hereinafter, for convenience of description, the first adhesive layer 530 will be mainly described.

In an embodiment, the first adhesive layer 530 may be formed to have the same size and shape as the first film layer 510 and/or the second film layer 520. That is, in a plan view, the circumferential line of the first adhesive layer 530 may coincide with the circumferential line of the first film layer 510 and/or the circumferential line of the second film layer 520. As described below, this may be implemented by forming the first film layer 510, the second film layer 520, the first adhesive layer 530, and the second adhesive layer 540 in the same cutting process while being attached to each other.

The first adhesive layer 530 may have a second opening OP2. The second opening OP2 may be an opening formed in the first adhesive layer 530, The second opening OP2 may correspond to the opening area OA. In an embodiment, the second opening OP2 may correspond to the first opening OP1. In other words, the second opening OP2 may overlap the first opening OP1 in a plan view. The second opening OP2 may have the same size and shape as the first opening OP1 and may have the same opening circumference as the first opening OP1.

Similarly, the second adhesive layer 540 may be formed to have the same size and shape as the first film layer 510 and/or the second film layer 520, and in a plan view, the circumferential line of the second adhesive layer 540 may coincide with the circumferential line of the first film layer 510 and/or the circumferential line of the second film layer 520. In addition, the second adhesive layer 540 may have a third opening OP3. The third opening OP3 may be an opening formed in the second adhesive layer 540. The third opening OP3 may correspond to the opening area OA. In an embodiment, the third opening OP3 may correspond to the first opening OP1.

In the process of manufacturing the display module 2 and/or the display device, the protective film 500 may be attached to the display panel 10, and may prevent impurities from penetrating into the through hole passing through some or all of the layers constituting the display panel 10. In this case, the through hole passing through some or all of the layers constituting the display panel 10 may be in a state in which the component 70 is not provided or is provided. In the latter case, when the second adhesive layer 540 contacts the component 70, malfunction of the component 70 may be caused in some cases. Alternatively, in the process of attaching the protective film 500 to the display panel 10, the pressure applied to the first film layer 510 may be transferred to the component 70 through the second adhesive layer 540, and thus, the component 70 may be damaged.

According to embodiments, the first adhesive layer 530 and the second adhesive layer 540 also respectively have the second opening OP2 and the third opening OP3 corresponding to the opening area OA, which may prevent the malfunction and damage described above. That is, the first adhesive layer 530 and the second adhesive layer 540 are formed as closed loops along the circumference of the through hole and do not overlap the through hole. Therefore, embodiments of the present disclosure may effectively prevent the component 70 from being unintentionally damaged in the process of manufacturing the display module 2 or a display device including the display module 2, and pressure applied to the first film layer 510 may be prevented from being transferred to the component 70 through the second adhesive layer 540. In addition, because the through hole passing through some or all of the layers constituting the display panel 10 overlaps only the first film layer 510 that is transparent, light transmittance may be increased, and thus, the inside of the through hole passing through some or all of the layers constituting the display panel 10 may be inspected while the through hole passing through some or all of the layers constituting the display panel 10 is shielded.

Referring to FIGS. 5 and 6, the protective film 500 may include an alignment pattern AP. The alignment pattern AP may have one or more shapes formed on at least a portion of the circumference of the protective film 500, and may be used to align the position between the protective film 500 and the display panel 10. In an embodiment, the alignment pattern AP may be a concave pattern. For example, the alignment pattern AP may form a concave portion at a corner where a first edge E1 of the protective film 500 and a second edge E2 of the protective film 500 adjacent to the first edge E1 meet each other in a plan view. This concave portion may be defined as a first concave portion RC1. In addition, the alignment pattern AP may form a concave portion at a corner where the second edge E2 and a third edge E3 of the protective film 500 adjacent to the second edge E2 meet each other. This concave portion may be defined as a second concave portion RC2. As described above, in an embodiment, the protective film 500 may include an alignment pattern AP including the first concave portion RC1 and the second concave portion RC2, but is not limited thereto. For example, in embodiments, the alignment pattern AP may include only one of the first concave portion RC1 and the second concave portion RC2, or may include three or more concave portions, such as further including a third concave portion formed at another corner. In addition, the shape of the alignment pattern AP is not limited to a concave shape, and a convex portion or various shapes for optical camera recognition may be used according to embodiments. Hereinafter, for convenience of description, a case in which the alignment pattern AP includes a concave portion will be mainly described.

Because the protective film 500 has a structure in which the first film layer 510, the second film layer 520, the first adhesive layer 530, and the second adhesive layer 540 are stacked, the alignment pattern AP may include patterns of the first film layer 510, the second film layer 520, the first adhesive layer 530, and the second adhesive layer 540. For example, the alignment pattern AP may include a first pattern AP1 formed on at least a portion of the circumference of the first film layer 510, a second pattern AP2 formed on at least a portion of the circumference of the second film layer 520, a third pattern AP3 formed on at least a portion of the circumference of the first adhesive layer 530, and a fourth pattern AP4 formed on at least a portion of the circumference of the second adhesive layer 540. That is, the first to fourth patterns AP1 to AP4 may also include concave portions at corners.

In other words, the first pattern AP1 and the second pattern AP2 may overlap each other in a plan view. The third pattern AP3 and the fourth pattern AP4 may also overlap each other in a plan view. Also, the third pattern AP3 and the fourth pattern AP4 may overlap the first pattern AP1 and the second pattern AP2 in a plan view.

When aligning the relative positions of the protective film 500 and the display panel 10 by using an optical camera, the optical camera determines the position of the protective film 500 by recognizing the alignment pattern AP of the protective film 500, particularly, the second pattern AP2 of the second film layer 520 that is opaque. The second film layer 520 has the same size and shape as the second adhesive layer 540 directly attached to the display panel 10, and the second pattern AP2 is positioned adjacent to the second adhesive layer 540. Thus, position alignment between the display panel 10 and the protective film 500 may be accurately achieved.

In an embodiment, the first concave portion RC1 and the second concave portion RC2 may have the same shape. For example, as shown in FIG. 6, the first concave portion RC1 may have a shape that is concave and recessed at a right angle. That is, an angle between the first side and the second side of a concave portion constituting the first concave portion RC1 may be about 90 degrees. In addition, the second concave portion RC2 may also have a shape in which a corner is concavely recessed at a right angle. As such, the first concave portion RC1 and the second concave portion RC2 may have shapes concavely recessed at the same angle.

Alternatively, in an embodiment, the first concave portion RC1 and the second concave portion RC2 may have different shapes. For example, the first concave portion RC1 and the second concave portion RC2 may have shapes that are concavely recessed at different angles. The first concave portion RC1 may be concavely recessed at a right angle, and the second concave portion RC2 may be concavely recessed at an obtuse angle. In this embodiment, recognition of the alignment pattern AP by the optical camera may be improved.

Still referring to FIGS. 5 and 6, in an embodiment, the protective film 500 may further include an additional concave portion ARC. In this case, it will be understood that the additional concave portion ARC may be formed in the first film layer 510, the second film layer 520, the first adhesive layer 530, and the second adhesive layer 540 in a thickness direction. The additional concave portion ARC may be formed on one side of the circumference of the protective film 500 in a plan view. When the protective film 500 is attached to the display panel 10, another sensor or the like may be positioned on a portion of the display panel 10 corresponding to one side of the protective film 500. In this case, in the process of attaching the protective film 500, there is a risk of damage due to pressure being applied to the other sensor or the like. The protective film 500 may effectively prevent the other sensor or the like from being damaged during the attachment process of the protective film 500 by having the additional concave portion ARC.

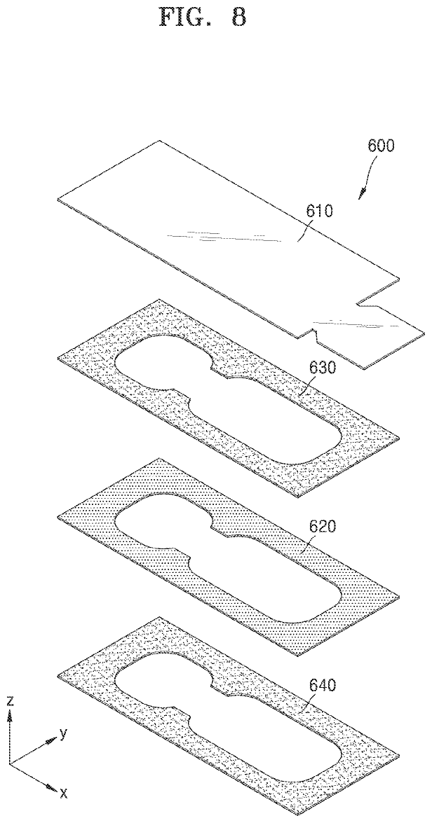

FIG. 7 is an exploded perspective view schematically illustrating a protective film 500 according to an embodiment. Since the protective film 500 of FIG. 7 is similar to that the protective film 500 as described above, for convenience of explanation, a further description of components and technical aspects previously described may be omitted, and only differences will be described below.

Referring to FIG. 7, the protective film 500 may include a first film layer 510, a second film layer 520, a first adhesive layer 530, and a second adhesive layer 540, as described above. In an embodiment, a stacking order may be different from that described above.

The first film layer 510 may shield a portion of the display panel 10, for example, the opening area OA. The first film layer 510 may have a larger area than the opening area OA to shield the opening area OA. In this case, the first film layer 510 may include a transparent material, as described above.

In addition, a gripping portion 550 may be positioned on one side of the first film layer 510. The gripping portion 550 may be formed integrally with the first film layer 510. The gripping portion 550 may include the same material as the first film layer 510, for example, a transparent material.

The second film layer 520 may be disposed on a side opposite to the display panel 10 in the first film layer 510. That is, the first film layer 510 may be disposed between the second film layer 520 and the display panel 10. The second film layer 520 may include an opaque material. The second film layer 520 may be formed to have the same size and shape as the first film layer 510. The second film layer 520 may have a first opening OP1 corresponding to the opening area OA.

The first adhesive layer 530 may be disposed between the first film layer 510 and the second film layer 520. The second adhesive layer 540 may be disposed between the first film layer 510 and the display panel 10. The first adhesive layer 530 and the second adhesive layer 540 may each include, for example, a pressure-sensitive adhesive material. The first adhesive layer 530 and the second adhesive layer 540 may each have the same size and shape as the first film layer 510 and/or the second film layer 520. Also, the first adhesive layer 530 and the second adhesive layer 540 may respectively have a second opening OP2 and a third opening OP3 corresponding to the first opening OP1.

Thus, in an embodiment, the opening area OA or the through hole passing through some or all of the layers constituting the display panel 10 may overlap only the first film layer 510 that is transparent. The first film layer 510 may shield the through hole passing through some or all of the layers constituting the display panel 10, and the second film layer 520, the first adhesive layer 530, and the second adhesive layer 540 may be arranged in a closed loop along the circumference of the through hole passing through some or all of the layers constituting the display panel 10.

In addition, the protective film 500 may include an alignment pattern AP, as described above. The alignment pattern AP may be formed in the second film layer 520, the first adhesive layer 530, the first film layer 510, and the second adhesive layer 540, and may include first through fourth patterns AP1, AP2, AP3 and AP4.

Accordingly, in embodiments of the present disclosure, the inside of the through hole passing through some or all of the layers constituting the display panel 10 may be inspected while shielding the through hole through the first film layer 510 that is transparent. In addition, because the protective film 500 and the display panel 10 may be aligned with each other through the opaque second film layer 520 having the same circumferential line as the first film layer 510, the first film layer 510 may more accurately shield the through hole passing through some or all of the layers constituting the display panel 10.

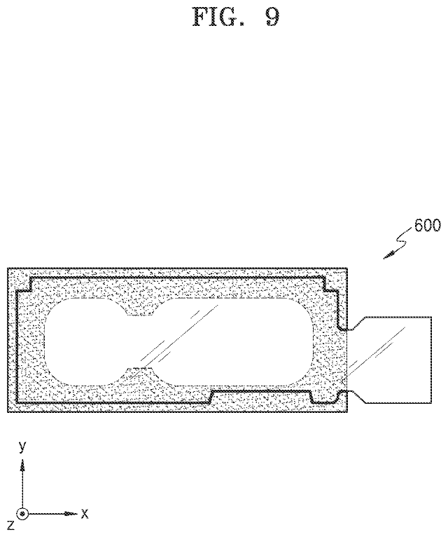

FIGS. 8 and 9 are views schematically illustrating a method of manufacturing a display module according to an embodiment. Hereinafter, for convenience of description, a method of manufacturing the display module shown in FIG. 3 will be mainly described.

Referring to FIG. 8, a film assembly layer 600 may be formed by sequentially arranging a first film layer 610, a first adhesive layer 630, a second film layer 620, and a second adhesive layer 640. In this case, the second film layer 620, the first adhesive layer 630, and the second adhesive layer 640 may each have an opening in the center. The openings of the second film layer 620, the first adhesive layer 630, and the second adhesive layer 640 may overlap one another in a plan view and may have the same size and shape.

Referring to FIG. 9, the film assembly layer 600 may be cut at the circumference thereof along a preset line. Accordingly, the film assembly layer 600 may be cut to form the protective film 500. That is, the first film layer 610 may be cut to form the first film layer 510, the second film layer 620 may be cut to form the second film layer 520, and the first adhesive layer 630 and the second adhesive layer 640 may be cut to form the first adhesive layer 530 and the second adhesive layer 540, respectively.

In this way, as the circumferences of the first film layer 610, the first adhesive layer 630, the second film layer 620, and the second adhesive layer 640 are simultaneously cut in a state in which the first film layer 610, the first adhesive layer 630, the second film layer 620, and the second adhesive layer 640 are stacked, the first film layer 510, the first adhesive layer 530, the second film layer 520, and the second adhesive layer 540 may all have the same circumferential line. Accordingly, attachment tolerance, which may occur due to slippage or the like when the first film layer 510, the first adhesive layer 530, the second film layer 520, and the second adhesive layer 540 are first formed and then the respective layers are attached to each other, may be prevented. Also, failure to attach the protective film 500 to the correct position of the display panel 10 due to the attachment tolerance may be prevented. FIG. 9 shows that the film assembly layer 600 is cut along a line indicated by a thick solid line to form one protective film 500. However, it will be understood that the film assembly layer 600 may form a plurality of protective films 500 according to embodiments.

Next, the protective film 500 may be attached to the display panel 10 to correspond to the display panel 10, for example, the opening area OA. Accordingly, the display module 2 as shown in FIG. 3 may be manufactured. As described above, in the display module 2, the inside of the opening area OA, that is, the inside of the through hole, may be inspected. In this case, because only the first film layer 510 that is transparent shields the opening area OA, the inspection of the inside of the through hole passing through some or all of the layers constituting the display panel 10 may be facilitated.

According to embodiments of the disclosure, a display module capable of reducing the probability of damage occurring during a manufacturing process may be implemented.

While the present disclosure has been particularly shown and described with reference to embodiments thereof, it will be understood by those of ordinary skill in the art that various changes in form and detail may be made therein without departing from the spirit and scope of the present disclosure as defined by the following claims.

What is claimed is:

1. A display module, comprising:
a display panel having an opening area; and
a protective film covering the opening area,
wherein the protective film comprises:
a first film layer shielding the opening area, the first film layer being transparent;
a second film layer disposed between the display panel and the first film layer, the second film layer being opaque;
a first adhesive layer disposed between the first film layer and the second film layer; and
a second adhesive layer disposed between the second film layer and the display panel.

2. The display module of claim 1, further comprising:
a component disposed in the opening area.

3. The display module of claim 1, wherein a circumferential line of the first film layer coincides with a circumferential line of the second film layer in a plan view.

4. The display module of claim 3, wherein a circumferential line of the first adhesive layer and a circumferential line of the second adhesive layer coincide with the circumferential line of the first film layer and the circumferential line of the second film layer in the plan view.

5. The display module of claim 1, wherein the protective film further comprises:
an alignment pattern formed on at least a portion of a circumference of the protective film.

6. The display module of claim 5, wherein the alignment pattern has a first concave portion that is concave at a first corner where a first edge of the protective film meets a second edge of the protective film.

7. The display module of claim 6, wherein the alignment pattern has a second concave portion that is concave at a second corner where the second edge of the protective film meets a third edge of the protective film,
wherein the first concave portion and the second concave portion have shapes concavely recessed at a same angle.

8. The display module of claim 5, wherein the alignment pattern comprises:
a first pattern formed on at least a portion of a circumference of the first film layer; and
a second pattern overlapping the first pattern on a circumference of the second film layer.

9. The display module of claim 8, wherein the alignment pattern further comprises:
a third pattern overlapping the second pattern on a circumference of the first adhesive layer; and
a fourth pattern overlapping the second pattern on a circumference of the second adhesive layer.

10. The display module of claim 1, wherein the second film layer has a first opening corresponding to the opening area.

11. The display module of claim 10, wherein the second film layer forms a closed loop along a circumference of the first film layer.

12. The display module of claim 10, wherein the first adhesive layer and the second adhesive layer respectively have a second opening and a third opening, which overlap the first opening in a plan view.

13. The display module of claim 1, wherein the protective film further comprises:
a concave portion disposed on one side of a circumference of the protective film.

14. The display module of claim 1, further comprising:
a gripping portion disposed on one side of the first film layer and comprising a transparent material.

15. A display module, comprising:
a display panel having an opening area; and
a protective film covering the opening area,
wherein the protective film comprises:
a first film layer shielding the opening area, the first film layer being transparent;
a second film layer disposed on a side of the first film layer opposite to the display panel, the second film layer being opaque;
a first adhesive layer disposed between the first film layer and the second film layer; and
a second adhesive layer disposed between the first film layer and the display panel.

16. The display module of claim 15, wherein a circumferential line of the first film layer coincides with a circumferential line of the second film layer in a plan view.

17. The display module of claim 15, wherein the protective film further comprises:
an alignment pattern formed on at least a portion of a circumference of the protective film.

18. A method of manufacturing a display module, the method comprising:
forming a film assembly layer by sequentially stacking, in a thickness direction, a transparent first film layer, a first adhesive layer, an opaque second film layer, and a second adhesive layer;
forming a protective film by cutting the film assembly layer in the thickness direction to form a pattern on a circumference of the film assembly layer in a plan view;
aligning the protective film with a display panel by recognizing the pattern of the protective film; and
attaching the protective film to cover an opening area of the display panel.

19. The method of claim 18, wherein the second film layer has a first opening exposing the opening area of the display panel, inside a circumference of the second film layer.

20. The method of claim 19, further comprising:
inspecting a component inside the opening area through the first opening from outside of the protective film.
